(19) United States
(12) Patent Application Publication
(10) Pub. No.: US 2011/0051368 A1
(43) Pub. Date: Mar. 3, 2011

(54) EXTERNAL THERMAL DEVICE AND RELATED ELECTRONIC DEVICE

(76) Inventors: Chuan-Liang Chang, Taipei County (TW); Chia-Ming Chuang, Tainan County (TW)

(21) Appl. No.: 12/717,940

(22) Filed: Mar. 4, 2010

(30) Foreign Application Priority Data
Sep. 2, 2009 (TW) 098216223

(51) Int. Cl. H05K 7/20; F28F 7/00

(52) U.S. Cl. 361/695; 165/185; 361/688

(57) ABSTRACT

An external thermal device for connecting to a thermal module disposed inside an electronic device is disclosed. The external thermal device includes a heat conducting component. An end of the heat conducting component is for inserting into an opening of the electronic device so as to connect to the thermal module in a removable manner. The heat conducting component is for conducting heat transmitted from the thermal module. The external thermal device further includes a heat dissipating component or a heat storage component disposed on the other end of the heat conducting component for dissipating or storing heat transmitted from the heat conducting component.

### BACKGROUND OF THE INVENTION

1. Field of the Invention

The present invention relates to a thermal device, and more particularly, to an external thermal device connected to a thermal module disposed inside an electronic device.

2. Description of the Prior Art

With the advanced technology, heat dissipating efficiency becomes an important issue in an application of a heat dissipating system. However, the conventional heat dissipating methods are unable to dissipate huge heat generated by a heat source with high power effectively, and various advanced heat dissipating methods are designed to dissipate the heat so as to keep an electronic device in a normal working temperature. Conventional air cooling systems with a fan have drawbacks, such as noise and power consumption. A modern electronic product trends toward a small size, and the conventional heat dissipating component, such as a fan, disposed inside a small space of the electronic product can not dissipate the heat effectively. Thus, design of a thermal device capable of dissipating the heat generated by inner components of the electronic device is an important issue in the electronic industry.

### SUMMARY OF THE INVENTION

The present invention provides an external thermal device connected to a thermal module disposed inside an electronic device for solving above drawbacks.

According to the claimed invention, an external thermal device includes a heat conducting component, an end of the heat conducting component being for inserting into an opening of an electronic device so as to connect to a thermal module disposed inside the electronic device in a removable manner, and the heat conducting component being for conducting heat transmitted from the thermal module, and a heat dissipating component disposed on the other end of the heat conducting component for dissipating heat transmitted from the heat conducting component.

According to the claimed invention, an electronic device includes a housing whereon an opening is formed, a heat source disposed inside the housing, a thermal module installed inside the housing and disposed on a side of the heat source for dissipating heat generated by the heat source, and an external thermal device. The external thermal device includes a heat conducting component, an end of the heat conducting component being for inserting into the opening on the housing so as to connect to the thermal module in a removable manner, and the heat conducting component being for conducting heat transmitted from the thermal module, and a heat dissipating component disposed on the other end of the heat conducting component for dissipating heat transmitted from the heat conducting component.

According to the claimed invention, an external thermal device includes a heat conducting component, an end of the heat conducting component being for inserting into an opening of an electronic device so as to connect to a thermal module disposed inside the electronic device in a removable manner, and the heat conducting component being for conducting heat transmitted from the thermal module, and a heat storage component disposed on the other end of the heat conducting component for storing heat transmitted from the heat conducting component.

According to the claimed invention, an electronic device includes a housing whereon an opening is formed, a heat source disposed inside the housing, a thermal module installed inside the housing and disposed on a side of the heat source for dissipating heat generated by the heat source, and an external thermal device. The external thermal device includes a heat conducting component, an end of the heat conducting component being for inserting into the opening on the housing so as to connect to the thermal module in a removable manner, and the heat conducting component being for conducting heat transmitted from the thermal module, and a heat storage component disposed on the other end of the heat conducting component for storing heat transmitted from the heat conducting component.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an electronic device according to a first embodiment of the present invention.

FIG. 2 is a diagram of a thermal module and an external thermal device according to a second embodiment of the present invention.

FIG. 3 is a diagram of the thermal module and the external thermal device according to a third embodiment of the present invention.

FIG. 4 is a diagram of the electronic device according to a fourth embodiment of the present invention.

### DETAILED DESCRIPTION

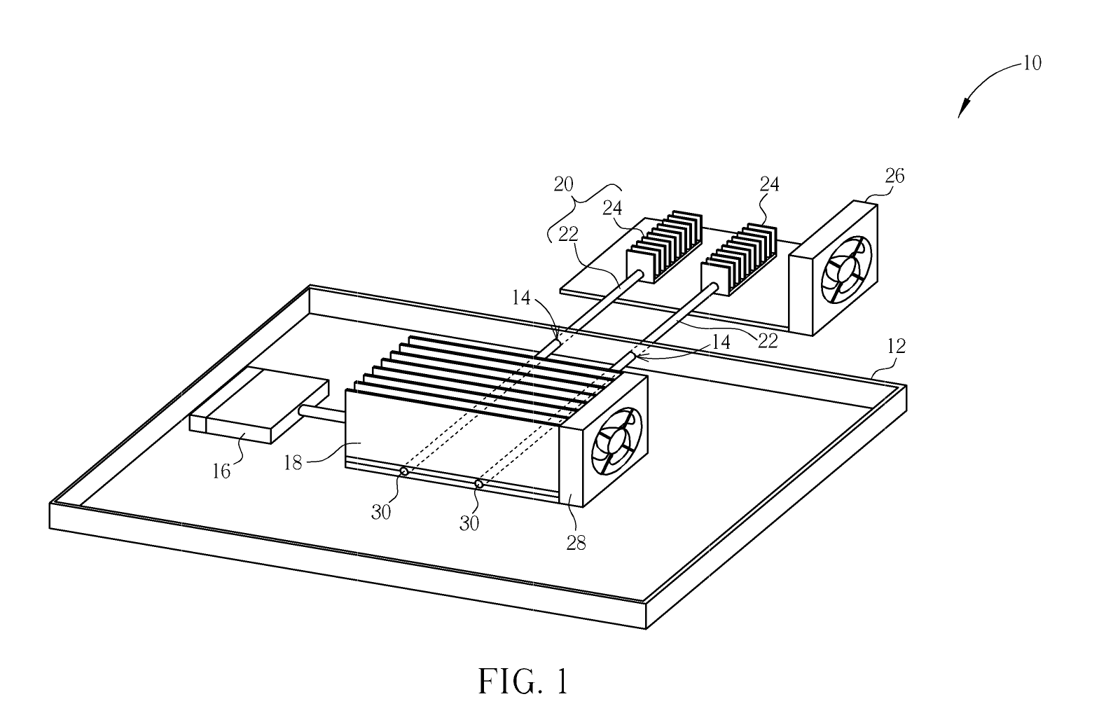

Please refer to FIG. 1. FIG. 1 is a diagram of an electronic device 10 according to a first embodiment of the present invention. The electronic device 10 includes a housing 12 whereon an opening 14 is formed, and a heat source 16 disposed inside the housing 12. The heat source 16 can be an electronic component, such as a chip and so on. The electronic device 10 further includes a thermal module 18 installed inside the housing 12 and disposed on a side of the heat source 16 for dissipating heat generated by the heat source 16. The electronic device 10 further includes an external thermal device 20. The external thermal device 20 includes at least one heat conducting component 22. The heat conducting component 22 can be a metal stick. An end of the heat conducting component 22 is for inserting into the opening 14 on the housing 12 so as to connect to the thermal module 18 in a removable manner. The heat conducting component 22 can be connected to the thermal module 18 in a tight fit manner. The heat conducting component 22 can further be clamped with the thermal module 18. The heat conducting component 22 is for transmitting the heat from the thermal module 18.

The external thermal module 20 further includes at least one heat dissipating component 24 disposed on an end of the heat conducting component 22 for dissipating the heat from the thermal module 18 transmitted from the heat conducting component 22. The heat dissipating component 24 can be a heat sink. The external thermal module 20 can further include an external fan 26 disposed on a side of the heat dissipating component 24 for dissipating the heat from the heat dissipating component 24. In addition, the electronic device 10 can further include a fan 28 disposed inside the housing 12 for dissipating the heat from the thermal module 18. The electronic device 10 can further include a switch 30 electrically connected to the fan 28. The end of the heat conducting component 22 is inserted into the opening 14 of the electronic device 10 for actuating the switch 30, so that the switch 30 can adjust a rotary speed of the fan 28 or turning on/off the fan 28. Positions and numbers of the heat conducting component 22 and the heat dissipating component 24 are not limited to the above-mentioned embodiment and depend on actual demand.

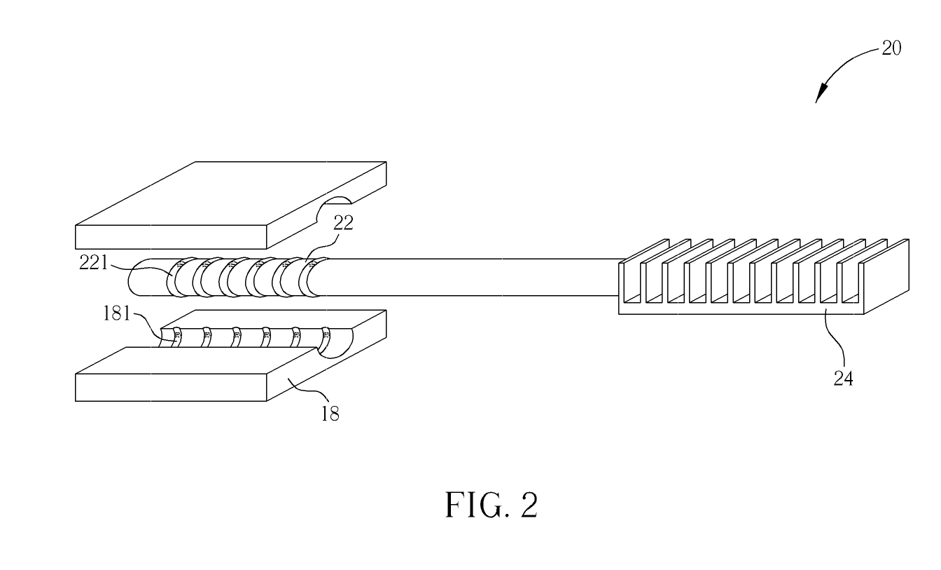

Please refer to FIG. 2. FIG. 2 is a diagram of the thermal module 18 and the external thermal device 20 according to a second embodiment of the present invention. In order to increase a heat dissipating efficiency of the heat conducting component 22, a plurality of protruding parts 221 can be formed on the heat conducting component 22 so as to increase a contact area for increasing the heat dissipating efficiency. The protruding part 221 can be a clipping ring. In addition, a plurality of corresponding sunken parts 181 can be formed on the thermal module 18 for wedging with the plurality of protruding parts 221 of the heat conducting component 22. The plurality of protruding parts 221 and the plurality of sunken parts 181 can be for increasing the contact area between the heat conducting component 22 and the thermal module 18. The plurality of protruding parts 221 of the heat conducting component 22 can be made of wear-resisting material so as to prevent the protruding part 221 from being worn when the protruding parts 221 of the heat conducting component 22 combine with the sunken parts 181 of the thermal module 18. Positions, numbers, and shapes of the protruding parts 221 and the sunken parts 181 are not limited to this embodiment and depend on design demand.

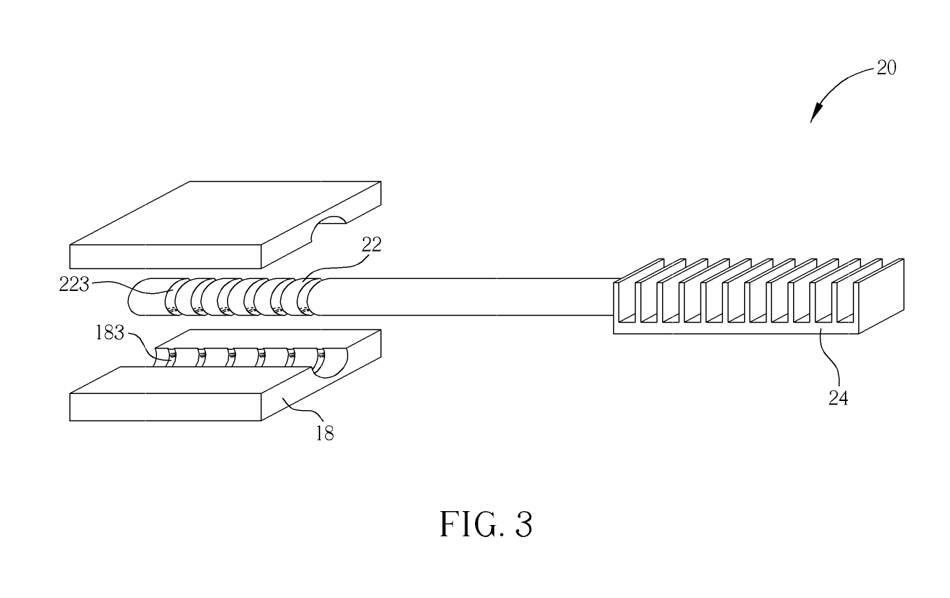

Positions of the protruding parts 221 and the sunken parts 181 in the above-mentioned embodiment can be exchanged with each other. Please refer to FIG. 3. FIG. 3 is a diagram of the thermal module 18 and the external thermal device 20 according to a third embodiment of the present invention. Comparing to the second embodiment, a plurality of sunken parts 223 can be formed on the heat conducting component 22 in the third embodiment so as to increase the contact area for improving the heat dissipating efficiency. In addition, a plurality of corresponding protruding parts 183 can be formed on the thermal module 18 for wedging with the plurality of sunken parts 223 of the heat conducting component 22. The plurality of sunken parts 223 and the plurality of protruding parts 183 are for increasing the contact area between the heat conducting component 22 and the thermal module 18. The plurality of protruding parts 183 of the thermal module 18 can be made of wear-resisting material so as to prevent the protruding part 183 from being worn when the protruding parts 183 of the thermal module 18 combine with the sunken parts 223 of the heat conducting component 22. Positions, numbers, and shapes of the sunken parts 223 and the protruding parts 183 are not limited to this embodiment and depend on design demand.

As shown in FIG. 1 to FIG. 3, the external thermal device 20 of the present invention can be a stick-shaped structure. The external thermal device 20 is inserted into the opening 14 on the housing 12 and connected to the thermal module 18 disposed inside the electronic device 10. When the external thermal device 20 is connected to the thermal module 18, there is no thermal connection of the thermal module 18 and the housing 12, so that temperature of the opening 14 is not increased by the heat from the thermal module 18, and the electronic device 10 only utilizes the fan 28 to dissipate the heat from the thermal module 18 uniformly. On the other hand, when the external thermal device 20 is connected to the thermal module 18, the heat conducting component 22 can transmit the heat from the thermal module 18 to the heat dissipating component 24, so that the electronic device 10 can utilize the heat dissipating component 24 disposed outside the electronic device 10 to dissipate the heat transmitted from the heat conducting component 22 rapidly. In addition, the external fan 26 can further dissipate the heat from the heat dissipating component 24 in a forced convection manner. In order to achieve preferred heat dissipating efficiency, the external thermal device 20 can be connected to the thermal module 18 in a tight fit manner, or the external thermal device 20 can further be clamped with the thermal module 18, so as to increase the contact area between the external thermal device 20 and the thermal module 18. In addition, the plurality of protruding parts and the plurality of corresponding sunken parts can be formed on the heat conducting component 22 of the external thermal device 20 and the thermal module 18, respectively. When the heat conducting component 22 is connected to the thermal module 18, the plurality of protruding parts can wedge with the plurality of corresponding sunken parts so as to increase the contact area and to improve stability. Connecting mechanism of the heat conducting component 22 and the thermal module 18 is not limited to the above-mentioned embodiment and depends on actual demand. For example, the heat conducting component 22 can be connected to the thermal module 18 tightly with an elastic clip, a screw, and so on.

Furthermore, when the end of the heat conducting component 22 is inserted into the opening 14 of the electronic device 10, the heat conducting component 22 can transmit the heat from the thermal module 18 to the heat dissipating component 24, so as to dissipate the heat out of the electronic device 10. The switch 30 can be actuated when the end of the heat conducting component 22 is inserted into the opening 14 of the electronic device 10, so that the switch 30 outputs a signal for controlling the fan 28. That is to say, the switch 30 can be actuated when the external thermal device 20 is connected to the thermal module 18 correctly, so as to adjust the rotary speed of the fan 28, such as decreasing the rotary speed of the fan 28 or shutting down the fan 28, because the external thermal device 20 can assist the thermal module 18 to dissipate the heat generated by the heat source 16. Therefore, the external thermal device 20 can economize power consumption of the electronic device 10 and decrease noise of the fan 28. Operating states (turn on/off) and rotary speed (high/low speed) of the external fan 26 and the fan 28 can be adjusted according to the heat generated by the heat source 16 and the connection between the thermal module 18 and the external thermal device 20.

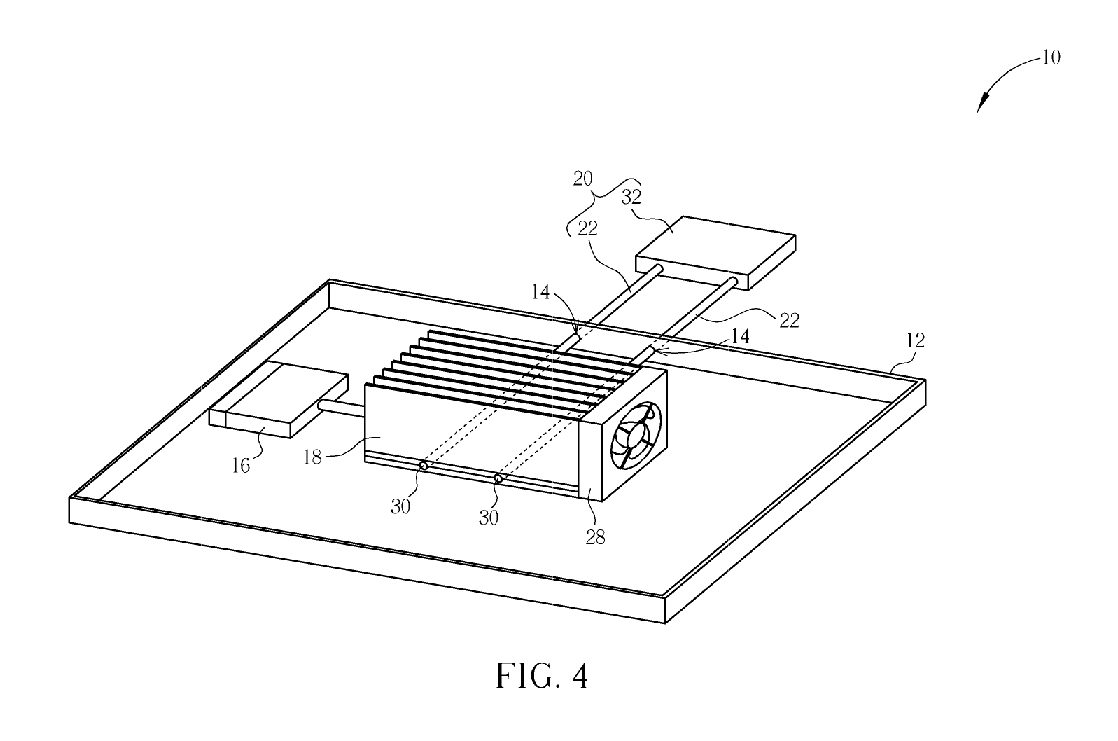

Please refer to FIG. 4. FIG. 4 is a diagram of the electronic device 10 according to a fourth embodiment of the present invention. In this embodiment, elements having the same numerals as the above-mentioned embodiment have the same structures and function, and the detailed description is omitted herein for simplicity. The electronic device 10 can further include a heat storage component 32 disposed on the other end of the heat conducting component 22 for storing the heat from the thermal module 18 transmitted from the heat conducting component 22. The heat storage component 32 can be a heater, such as a heating container whereinside essential oils can be accommodated. When the heat is transmitted from the heat conducting component 22 to the heat storage component 32, the heat storage component 32 can heat the essential oils for transpiring good smell. In addition, the heat storage component 32 can further be a heat conducting plate whereon objects intending to be warmed can be put, such as a thermos bottle. When the heat is transmitted from the heat conducting component 22 to the heat storage component 32, the heat storage component 32 can warm or heat the objects. Because the heat from the thermal module 18 transmitted from the heat conducting component 22 is waste heat, the heat storage component 32 can store the waste heat or recycle the waste heat to warm or heat other objects, such as an essential oil lamp, a water cup, and so on. Function of the heat storage component 32 is not limited to the above-mentioned embodiment and depends on actual demand.

Comparing to the prior art, the external thermal device of the present invention inserts the heat conducting component into the opening on the electronic device so as to connect to the thermal module disposed inside the electronic device directly, so that the external thermal device can transmit the heat from the thermal module out of the electronic device effectively. The plurality of protruding parts and the plurality of corresponding sunken parts can be formed on the heat conducting component and the thermal module for increasing the contact area between the external thermal device and the thermal module so as to improve the heat dissipating efficiency. In addition, the electronic device of the present invention can utilize the switch to detect whether the external thermal device is installed correctly and to adjust the rotary speed of the fan according to the detecting result, so as to economize the power and decrease the noise.

Those skilled in the art will readily observe that numerous modifications and alterations of the device and method may be made while retaining the teachings of the invention.

What is claimed is:

1. An external thermal device comprising:
a heat conducting component, an end of the heat conducting component being for inserting into an opening of an electronic device so as to connect to a thermal module disposed inside the electronic device in a removable manner, and the heat conducting component being for conducting heat transmitted from the thermal module; and
a heat dissipating component disposed on the other end of the heat conducting component for dissipating heat transmitted from the heat conducting component.

2. The external thermal device of claim 1 further comprising:
an external fan disposed on a side of the heat dissipating component for dissipating heat from the heat dissipating component.

3. The external thermal device of claim 1, wherein the heat conducting component is connected to the thermal module in a tight fit manner.

4. The external thermal device of claim 3, wherein the heat conducting component is clamped with the thermal module.

5. The external thermal device of claim 1, wherein a plurality of protruding parts is formed on the heat conducting component, and a plurality of sunken parts corresponding to the plurality of protruding parts is formed on the thermal module for wedging with the plurality of protruding parts when the heat conducting component is connected to the thermal module.

6. The external thermal device of claim 5, wherein the plurality of protruding parts is made of wear-resisting material.

7. The external thermal device of claim 1, wherein a plurality of sunken parts is formed on the heat conducting component, a plurality of protruding parts corresponding to the plurality of sunken parts is formed on the thermal module for wedging with the plurality of sunken parts when the heat conducting component is connected to the thermal module.

8. The external thermal device of claim 1, wherein the end of the heat conducting component inserts into the opening of the electronic device for actuating a switch disposed inside the electronic device so that the switch outputs a signal.

9. The external thermal device of claim 8, wherein the switch is for outputting the signal so as to adjust a rotary speed of a fan of the electronic device.

10. The external thermal device of claim 1, wherein the heat dissipating component is a metal stick.

11. An electronic device comprising:
a housing whereon an opening is formed;
a heat source disposed inside the housing;
a thermal module installed inside the housing and disposed on a side of the heat source for dissipating heat generated by the heat source; and
an external thermal device comprising:
a heat conducting component, an end of the heat conducting component being for inserting into the opening on the housing so as to connect to the thermal module in a removable manner, and the heat conducting component being for conducting heat transmitted from the thermal module; and
a heat dissipating component disposed on the other end of the heat conducting component for dissipating heat transmitted from the heat conducting component.

12. The electronic device of claim 11, wherein the external thermal device further comprises an external fan disposed on a side of the heat dissipating component for dissipating heat from the heat dissipating component.

13. The electronic device of claim 11, wherein the heat conducting component is connected to the thermal module in a tight fit manner.

14. The electronic device of claim 13, wherein the heat conducting component is clamped with the thermal module.

15. The electronic device of claim 11, wherein a plurality of protruding parts is formed on the heat conducting component, and a plurality of sunken parts corresponding to the plurality of protruding parts is formed on the thermal module for wedging with the plurality of protruding parts when the heat conducting component is connected to the thermal module.

16. The electronic device of claim 15, wherein the plurality of protruding parts is made of wear-resisting material.

17. The electronic device of claim 11, wherein a plurality of sunken parts is formed on the heat conducting component, and a plurality of protruding parts corresponding to the plurality of sunken parts is formed on the thermal module for wedging with the plurality of sunken parts when the heat conducting component is connected to the thermal module.

18. The electronic device of claim 11 further comprising:
a fan disposed inside the housing; and
a switch electrically connected to the fan for outputting a signal when the end of the heat conducting component inserts into the opening of the electronic device to actuate the switch so as to adjust a rotary speed of the fan.

19. An external thermal device comprising:
a heat conducting component, an end of the heat conducting component being for inserting into an opening of an electronic device so as to connect to a thermal module disposed inside the electronic device in a removable manner, and the heat conducting component being for conducting heat transmitted from the thermal module; and
a heat storage component disposed on the other end of the heat conducting component for storing heat transmitted from the heat conducting component.

20. An electronic device comprising:
a housing whereon an opening is formed;
a heat source disposed inside the housing;
a thermal module installed inside the housing and disposed on a side of the heat source for dissipating heat generated by the heat source; and
an external thermal device comprising:
a heat conducting component, an end of the heat conducting component being for inserting into the opening on the housing so as to connect to the thermal module in a removable manner, and the heat conducting component being for conducting heat transmitted from the thermal module; and
a heat storage component disposed on the other end of the heat conducting component for storing heat transmitted from the heat conducting component.
